(19) United States
(12) Patent Application Publication
(10) Pub. No.: US 2026/0215010 A1
(43) Pub. Date: Jul. 23, 2026

(54) IMAGE SENSING DEVICE AND METHOD OF MANUFACTURING THE SAME

(71) Applicant: SK hynix Inc., Icheon-si (KR)

(72) Inventor: Min Ki NA, Icheon-si (KR)

(21) Appl. No.: 19/195,363

(22) Filed: Apr. 30, 2025

(30) Foreign Application Priority Data
Jan. 21, 2025 (KR) 10-2025-0008721

(51) Int. Cl. H10F 39/00; H04N 25/77; H10F 39/18

(52) U.S. Cl. CPC H10F 39/80373; H10F 39/014; H10F 39/018; H10F 39/182; H10F 39/805; H10F 39/8053; H10F 39/8063; H10F 39/807; H10F 39/809; H04N 25/77

(57) ABSTRACT

An image sensing device may include a substrate having a first surface and a second surface opposite to the first surface, a plurality of unit pixels supported by the substrate, each unit pixel configured to include a photoelectric conversion element that converts incident light into photocharge, and a transfer gate provided in each of the plurality of unit pixels to transfer the photocharge out of the photoelectric conversion element, the transfer gate extending vertically along a vertical direction from the first surface to the second surface of the substrate with a first length. In each unit pixel, the photoelectric conversion element is configured to extend along the vertical direction with a second length that is equal to or less than the first length of the transfer gate.

### PRIORITY CLAIM AND CROSS-REFERENCES TO RELATED APPLICATION

This patent document claims the priority and benefits of Korean application number 10-2025-0008721, filed on Jan. 21, 2025, in the Korean Intellectual Property Office, which is incorporated herein by reference in its entirety.

### TECHNICAL FIELD

Example embodiments relate to an image sensing device and a method of manufacturing the same.

### BACKGROUND

An image sensing device may include a pixel array and control logic. The pixel array may include a plurality of pixels. Each of the plurality of pixels may include a photoelectric conversion element configured to receive light and to generate an electrical signal. The control logic may drive the pixel array. The control logic may acquire pixel signals from a selected pixel to generate image data.

In the image sensing device, the image quality may be determined by an area of the photoelectric conversion element as well as transmission characteristics of charges generated by the photoelectric conversion element.

### SUMMARY

Example embodiments provide an image sensing device that may be capable of improving image quality.

Example embodiments provide a method of manufacturing the above-mentioned image sensing device.

According to example embodiments, there may be provided an image sensing device. The image sensing device may a substrate having a first surface and a second surface opposite to the first surface; a plurality of unit pixels supported by the substrate, each unit pixel configured to include a photoelectric conversion element that converts incident light into photocharge; and a transfer gate provided in each of the plurality of unit pixels to transfer the photocharge out of the photoelectric conversion element, the transfer gate extending vertically along a vertical direction from the first surface to the second surface of the substrate with a first length, wherein, in each unit pixel, the photoelectric conversion element is configured to extend along the vertical direction with a second length that is equal to or less than the first length of the transfer gate.

According to example embodiments, there may be provided an image sensing device. The image sensing device may include a first substrate and a second substrate. The first substrate may have a front surface and a back surface. The first substrate may include pixel elements and a first bonding layer electrically connected to the pixel elements, the pixel elements and the first bonding layer being disposed on the front surface, and the first substrate further include a light incidence element disposed on the back surface. The second substrate may be bonded to the first bonding layer and include a logic circuit on the front surface of the first substrate and a second bonding layer electrically connected to the logic circuit.

In example embodiments, each pixel element included in the first substrate may comprise: a transfer gate extends along a vertical direction with a first extension length in the first substrate; a photoelectric conversion element formed in the first substrate and surrounding a sidewall of the transfer gate, the photoelectric conversion element extending along the vertical direction with a second extension length that is equal to or less than the first extension length; and a floating diffusion region positioned on the front surface of the first substrate on one side of the photoelectric conversion element and configured to selectively receive charges generated by the photoelectric conversion element based on an operation of the transfer gate.

According to example embodiments, there may be provided a method of manufacturing an image sensing device. The method may comprise etching a front surface of a first substrate having unit pixels by a set depth to form a trench; implanting conductive impurities into the trench to form a photoelectric conversion element; forming a gate insulation layer on the front surface of the first substrate with the trench; forming a conductive layer on the gate insulation layer to fill the trench; patterning the conductive layer to form a transfer gate; implanting impurities onto a region disposed on the front surface of the first substrate and at one side of the transfer gate to form a floating diffusion region; and grinding a back surface of the first substrate to expose the transfer gate.

According to example embodiments, the transfer gate of the unit pixels may be configured to penetrate the pixel array substrate. The photoelectric conversion element may be formed to surround the sidewall of the transfer gate. Further, the photoelectric conversion element may be formed to have an extension length equal to or less than the vertical extension length of the transfer gate in the pixel array substrate. Accordingly, an entire area of the photoelectric conversion element may be controlled at a constant distance from the transfer gate to improve charge transfer characteristics to the floating diffusion region. By improving the charge transfer characteristics, Gm characteristics, conversion gain may be secured, and noises may be improved, which ultimately improves the image quality of the image sensing device.

### BRIEF DESCRIPTION OF THE DRAWINGS

The above and another aspects, features and advantages of the subject matter of the present disclosure will be more easily understood from the following detailed description taken in conjunction with the accompanying drawings.

FIG. 1 is a block diagram illustrating an image sensing device based on some implementations of the disclosed technology.

FIG. 2 is an equivalent circuit diagram illustrating a unit pixel based on some implementations of the disclosed technology.

FIG. 3 is a plan view illustrating a pixel array substrate based on some implementations of the disclosed technology.

FIG. 4 is a cross-sectional view of a pixel array substrate taken along a line A-A′ of FIG. 3.

FIG. 5 is a perspective view illustrating a transfer gate and a photoelectric conversion element based on some implementations of the disclosed technology.

FIGS. 6A and 6B show plan views illustrating a photoelectric conversion element, a transfer gate, and a gate insulation layer based on some implementations of the disclosed technology.

FIGS. 7A to 7H are cross-sectional views illustrating a method of manufacturing an image sensing device based on some implementations of the disclosed technology.

### DETAILED DESCRIPTION

The advantages and features of the present invention, and methods of achieving them, will become apparent upon reference to the embodiments described in detail with reference to the accompanying drawings. Throughout the specification, like reference numerals refer to like components.

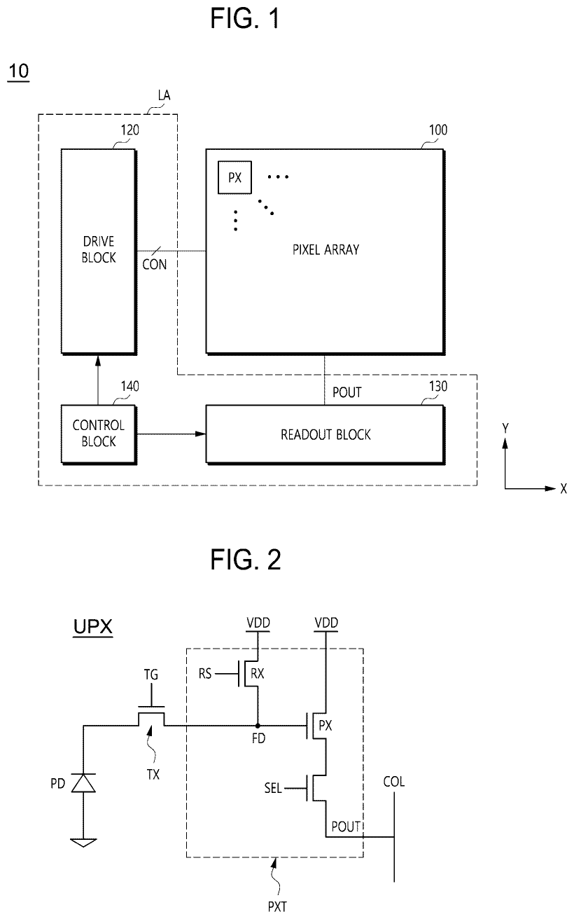

FIG. 1 is a block diagram illustrating an image sensing device in accordance with example embodiments.

Referring to FIG. 1, an image sensing device 10 may include a complementary metal oxide semiconductor image sensor (CIS) configured to convert a light into an electrical signal. In example embodiments, the light may include photons capable of producing a photoelectric effect. The light may also refer to electromagnetic radiation or electromagnetic waves corresponding to specific wavelength bands in the electromagnetic spectrum, including radio waves, microwaves, infrared rays, near-infrared rays, visible light, ultraviolet light, x-rays, gamma rays, or others.

The image sensing device 10 may include a pixel array 100 and a logic assembly LA.

The pixel array 100 may include a plurality of row lines (not shown), a plurality of column lines (not shown) and a plurality of pixels PXs that are arranged along the plurality of row lines and the plurality of column lines. In example embodiments, the plurality of row lines may extend parallel along an x-direction of the drawing. The plurality of column lines may extend parallel along a y-direction of the drawing perpendicular to the x-direction. The plurality of pixels PX may be controlled by the plurality of row lines and the plurality of column lines intersected with each other. The plurality of pixels PX may be arranged in a matrix form. In example embodiments, the pixels PX may include at least one unit pixel. In example embodiments, the unit pixel may be a structure including one photoelectric conversion element. The pixel PX may be interpreted as a structure including at least one unit pixel sharing one floating diffusion region.

The logic assembly LA may include, for example, a drive block 120, a readout block 130 and a control block 140.

The drive block 120 may drive the pixels PX of the pixel array 100 in response to a timing signal (not shown) outputted from the control block 140. For example, the drive block 120 may output at least one control signal CON for selecting and controlling the pixels PX in at least one row line of the plurality of row lines of the pixel array 100.

The readout block 130 may detect a pixel signal POUT outputted from the pixel array 100 under controls of the control block 140. The readout block 130 may generate image data from the detected pixel signal POUT. The image data may be pixel data in a digital form of an analog-to-digital conversion of a pixel signal in an analog form. To generate the pixel data in the digital form, the readout block 130 may further include a dual correlation sampler (not shown) and an analog-to-digital converter (not shown). In addition, the readout block 130 may further include a buffer circuit configured to temporarily store the pixel data outputted from the analog-to-digital converter and output the pixel data to the outside under the control of the control block 140.

The control block 140 may generate the timing signals for controlling the operation of the drive block 120 and the readout block 130.

In example embodiments, the image sensing device 10 may further include an external processor (ISP: image signal processor: not shown). Further, in response to a request from the external processor, the control block 140 may generate the timing signal in a timely manner. In example embodiments, the control block 140 may include a logic control circuit, a phase lock loop (PLL) circuit, a timing control circuit, a communication interface circuit, and the like.

As such, the pixel array 100 and the logic assembly LA may be organized in a three-dimensional stacked structure, or may be arranged in two dimensions.

FIG. 2 is an example of an equivalent circuit diagram illustrating a unit pixel in accordance with example embodiments. The pixel array 100 in FIG. 1 may include an array of such unit pixels for detecting incident light and to generate pixel signals representing an image in the incident light.

Referring to FIG. 2, a unit pixel UPX may include a photoelectric conversion element PD, a floating diffusion region FD, a transfer transistor TX and a pixel circuit PXT.

The transfer transistor TX may be connected between the photoelectric conversion element PD and the floating diffusion region FD. The transfer transistor TX may transfer charges generated by the photoelectric conversion element PD in response to incident light to the floating diffusion region FD based on a transfer gate signal TG. The transfer gate signal TG may be one of the control signals CON outputted from the drive block 120. In this example, the transfer transistor TX constitute a transfer gate for selectively transferring charges from the photoelectric conversion element PD to the floating diffusion region FD as part of the image readout operation.

For example, the pixel circuit PXT may include a reset transistor RX, a drive transistor DX and a selection transistor SX. The reset transistor RX may be connected between a power supply voltage terminal VDD and the floating diffusion region (FD node). The reset transistor RX may provide the power supply voltage VDD to the floating diffusion region FD based on a reset control signal RS. The drive transistor DX may be connected between the supply voltage terminal VDD and the selection transistor SX. The drive transistor DX may be turned on in response to a voltage in the floating diffusion region FD. The voltage of the floating diffusion region FD may be variable depending on an amount of the charges transferred from the photoelectric conversion element PD to the floating diffusion region FD. The selection transistor SX may be connected between the drive transistor DX and a column line COL. The selection transistor SX may, in response to a selection control signal SEL, provide the output voltage of the drive transistor DX to the column line COL as a pixel signal POUT.

In example embodiments, the pixel circuit PXT may be shared by the plurality of unit pixels UPX constituting the pixel PX.

The pixel circuit PXT may be operated as follows.

When the reset transistor RX may be turned on, the voltage in the floating diffusion region FD may be reset to the supply voltage VDD. After the floating diffusion region FD may be reset, when the select control signal SEL may be enabled, the selection transistor SX may be turned on to output the reset voltage, i.e., the supply voltage VDD, to the column line COL.

After resetting the column line COL, when the transfer transistor TX may be turned on, the charges generated in the photoelectric conversion element PD may be transferred to the floating diffusion region FD.

The drive transistor DX may be turned on based on the amount of charge accumulated in the floating diffusion region FD. Accordingly, the drive transistor DX may be operated as a source follower amplifier configured to amplify a voltage based on the amount of charge in the floating diffusion region FD.

When the selection control signal SEL may be enabled, the selection transistor SX may be turned on, such that the output voltage of the drive transistor DX may be outputted as the pixel signal via the column line COL.

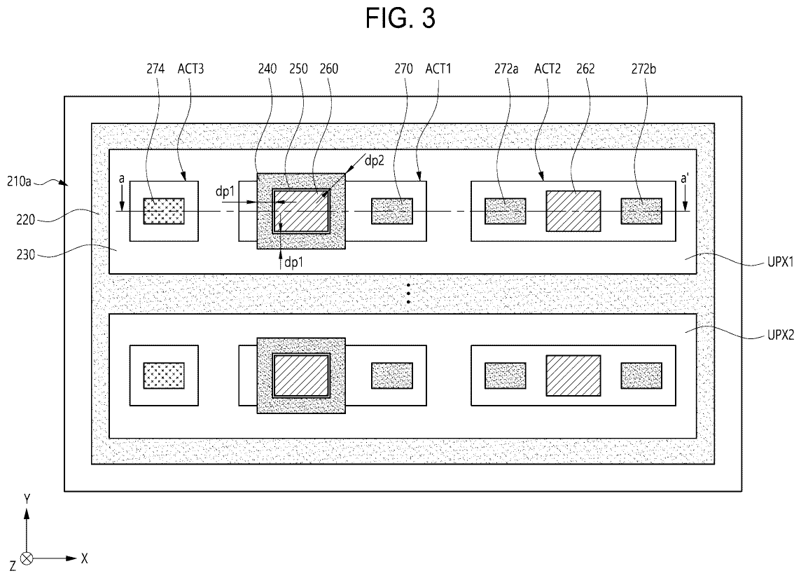

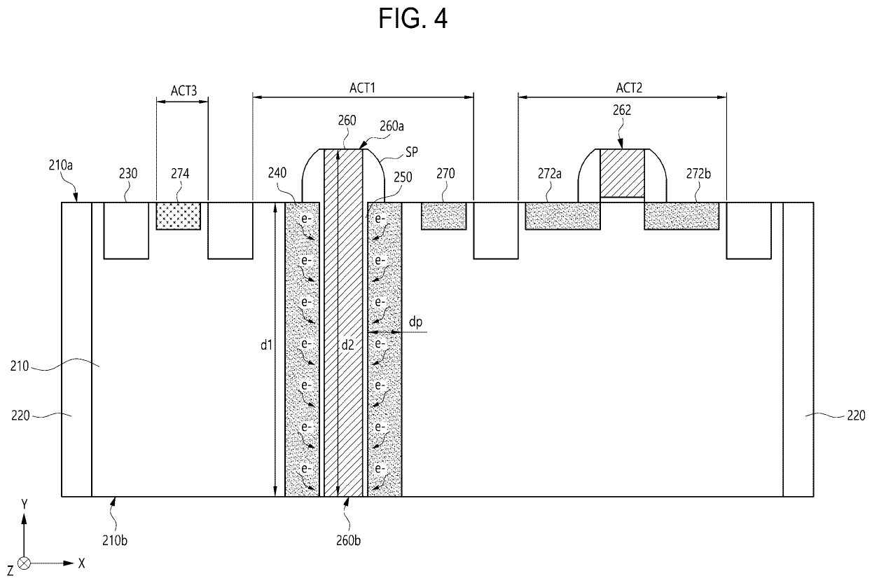

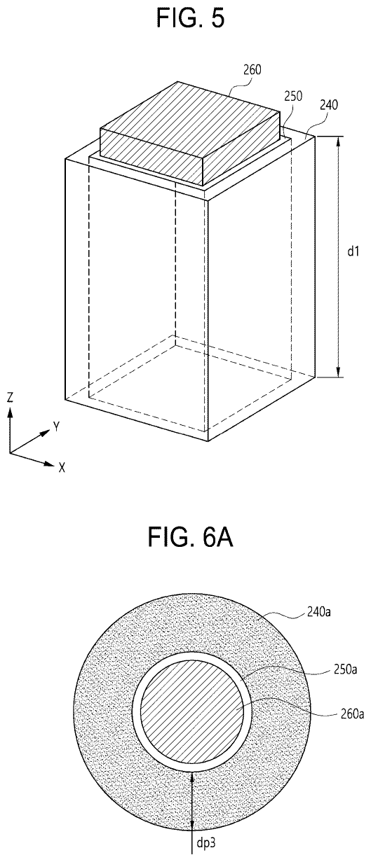

FIG. 3 is a plan view illustrating a unit pixel in accordance with example embodiments, FIG. 4 is a cross-sectional view of a unit pixel taken along a line a-a′ of FIG. 3, and FIG. 5 is a perspective view illustrating a transfer gate and a photoelectric conversion element in accordance with example embodiments.

Referring now to FIGS. 3 to 5, unit pixels UPX1 and UPX2 may be supported by a first substrate, e.g., being integrated or disposed on a first substrate, such as a pixel array substrate 210.

For example, each of the unit pixels UPX1 and UPX2 may be integrated or disposed in the pixel array substrate 210 defined by a pixel isolation layer 220. In the example, the pixel isolation layer 220 may be disposed to surround the unit pixels UPX1 and UPX2. The unit pixels UPX1 and UPX2 may include, for example, a photoelectric conversion element 240, a transfer gate 260, a floating diffusion region 270 and at least one transistor including a pixel circuit PXT (see FIG. 2). The transfer gate 260 is operated in response to a transfer gate control signal to selectively transfer the charges generated in the photoelectric conversion element 240 out of the photoelectric conversion element 240 into the floating diffusion region 270.

The pixel array substrate 210 may include bulk silicon or silicon-on-insulator (SOI). In example embodiments, the pixel array substrate 210 may include germanium silicide, indium antimonide, lead telluride compound, indium arsenide, indium phosphide, gallium arsenide, or gallium antimonide. The pixel array substrate 210 may also include an epitaxial growth layer. The pixel array substrate 210 may include, for example, first or second conductive impurities. For example, the first conductive type may be p-type, and the second conductive type may be n-type, which is the opposite of the first conductive type. The pixel array substrate 210 may include a first surface 210a corresponding to a front surface, and a second surface 210b corresponding to a back surface. For example, a vertical extension length from the first surface 210a to the second surface 210b of the pixel array substrate 210 may have a first length d1.

The pixel isolation layer 220 may be formed in a form of a grid in the pixel array substrate 210 to define areas for the plurality of unit pixels UPX1 and UPX2. For example, the pixel isolation layer 220 may extend in a continuous or discontinuous vertical direction from the first surface 210a to the second surface 210b of the pixel array substrate 200. In example embodiments, the vertical direction may refer to a direction perpendicular to the first surface 210a or second surface 210b of the substrate 200. The vertical extension length may refer to an extension length of a material extending in the vertical direction. The pixel isolation layer 220 may be formed in a deep trench type or a junction type. Further, the pixel isolation layer 220 may include an insulating layer or a conductive layer. The pixel isolation layer 220 may electrically and optically separate the unit pixels UPX1 and UPX2 from each other.

The photoelectric conversion element 240, the transfer gate 260, the floating diffusion region 270 and the transistor for pixel circuit PXT may be integrated in an active region of the unit pixels UPX1 and UPX2. For example, the active region may be defined by forming a device isolation layer 230 in the unit pixels UPX1 and UPX2. For example, the device isolation layer 230 may have a shallow trench isolation (STI) structure. The device isolation layer 230 may be formed to have a predetermined depth from the first surface 210a of the pixel array substrate 210. The device isolation layer 230 may have a shallower depth than the pixel isolation layer 220. In example embodiments, the device isolation layer 230 may be formed in the pixel array substrate 210 such that the active regions may include first to third active regions ACT1, ACT2 and ACT3.

For example, the transfer gate 260 may be located in the first active region ACT1. The transfer gate 260 may extend along a vertical direction, e.g., from a top of the first surface 210a to a top of the second surface 210b of the pixel array substrate 210.

For example, a first surface 260a of the transfer gate 260 may protrude a predetermined height from the first surface 210a of the pixel array substrate 210. A second surface 260b of the transfer gate 260 may be located in substantially the same plane as the second surface 210b of the pixel array substrate 210. Accordingly, the transfer gate 260 may have a second vertical extension length d2 that is greater than the first length d1.

The photoelectric conversion element 240 may be formed in the pixel array substrate 210. The photoelectric conversion element 240 may be formed to surround a sidewall of the transfer gate 260. To enable sufficient photoelectric charges to be generated by the photoelectric conversion element 240, the photoelectric conversion element 240 may have the first extension length d1 and extend in the vertical direction to penetrate the pixel array substrate 210 together with the transfer gate 260.

Alternatively, a vertical extension length of the photoelectric conversion element 240 in the pixel array substrate 210 may be equal to a vertical extension length of the transfer gate 260 in the pixel array substrate 210. In some cases, the vertical extension length of the photoelectric conversion element 240 in the pixel array substrate 210 may be less than the vertical extension length of the transfer gate 260 in the pixel array substrate 210. Accordingly, an entire region of the photoelectric conversion element 240 may face the transfer gate 260, such that charges, that is, photons may be generated from an entire region of the photoelectric conversion element 240.

The photoelectric conversion element 240 may be disposed on sides of the transfer gate 260. Referring to the example as shown in FIG. 4, the photoelectric conversion element 240 may have an inner sidewall and an outer sidewall, the inner sidewall closer to the transfer gate 260 as compared to the outer sidewall. From a surface cross-sectional viewpoint, an inner sidewall of the photoelectric conversion element 240 may overlap the sidewalls of the transfer gate 260. For example, the inner sidewalls of the photoelectric conversion element 240 may be disposed on sides of the sidewalls of the transfer gate 260. From a planar perspective, in the example as shown in FIGS. 3-5, the planar shape of the transfer gate 260 may be square. When the planar shape of the transfer gate 260 is a square, a width DP1 of the photoelectric conversion element 240 may be the same when the width is measured in directions along the x-axis and y-axis of FIG. 3. A width DP2 of the photoelectric conversion element 240 between a corner (or a vertex) of the transfer gate 260 and a corner (or a vertex) of the photoelectric conversion element 240 may be larger than the width DP1 of the photoelectric conversion element 240. The width DP2 is measured in a direction intersecting the directions along the x-axis and y-axis.

In the implementations, the entire area of the photoelectric conversion element 240 may be uniformly controlled by the transfer gate 260. As such, the photoelectric conversion element 240 may include conductive impurities having an opposite type to the pixel array substrate 210.

A gate insulation layer 250 may be interposed between the photoelectric conversion element 240 and the transfer gate 260.

The floating diffusion region 270 may be formed in the first active region ACT1 of one surface of the photoelectric conversion element 240. In the transfer gate 260, the floating diffusion region 270 may be disposed on one surface of the photoelectric conversion element 240. Under the control of the transfer gate 260, the charges generated in the photoelectric conversion element 240 may be selectively transferred to the floating diffusion region 270. The floating diffusion region 270 may also include conductive impurities of the opposite type to the pixel array substrate 210.

A gate 262 of at least one of the reset transistor RX, the drive transistor DX and the selection transistor SX including the pixel circuit PXT may be formed at a set position in the second active region ACT2. While FIGS. 3 and 4 illustrate an example where one gate 262 is formed in the second active region ACT2, gates of a plurality of transistors may be integrated in the second active region ACT2, without limitation. For example, an upper surface 262a of the gate 262 may be located in the same plane as the upper surface 260a of the transfer gate 260. A source 272a and a drain 272b may be formed in the second active region ACT2 on either surface of the gate 262. Accordingly, at least one of at least one the pixel transistor including the pixel circuit PXT, such as a reset transistor RX, the drive transistor DX, the selection transistor SX, may be formed in the second active region ACT2. The reference numeral SP may refer to a sidewall spacer of the transfer gate 260 and the gate 262 of the pixel transistor.

The third active region ACT may be provided with a substrate contact region 274. The substrate contact region 274 may be electrically connected to a subsequent conductive line (not shown) to apply a substrate voltage to the pixel array substrate 210 compartmentalized by the pixel isolation layer 220. In example embodiments, the floating diffusion region 270, the source 272a and the drain 272b may include conductive impurities of an opposite type to the conductive type of the pixel array substrate 210. In some implementations, the substrate contact region 274 may include the same type of conductive impurities as the pixel array substrate 210.

The photoelectric conversion element 240 of example embodiments may be formed to surround the outer circumference of the transfer gate 260. In the example, the entire photoelectric conversion element 240, i.e., from top to bottom of the photoelectric conversion element 240, may be equidistantly spaced from the sidewall of the transfer gate 260a. Therefore, the photoelectric charges E generated by the photoelectric conversion element 240 may respond uniformly to the signal applied to the transfer gate 260a. The photoelectric charges E may then be transferred to the floating diffusion region 270.

Accordingly, a distance deviation between the photoelectric conversion element 240 and the transfer gate 260 may be reduced for each unit pixel, thereby improving the charge transfer characteristics of the photoelectric conversion element 240. As a result, lag phenomenon, transconductance characteristics, conversion gain, and noise may be improved so that image quality may be improved.

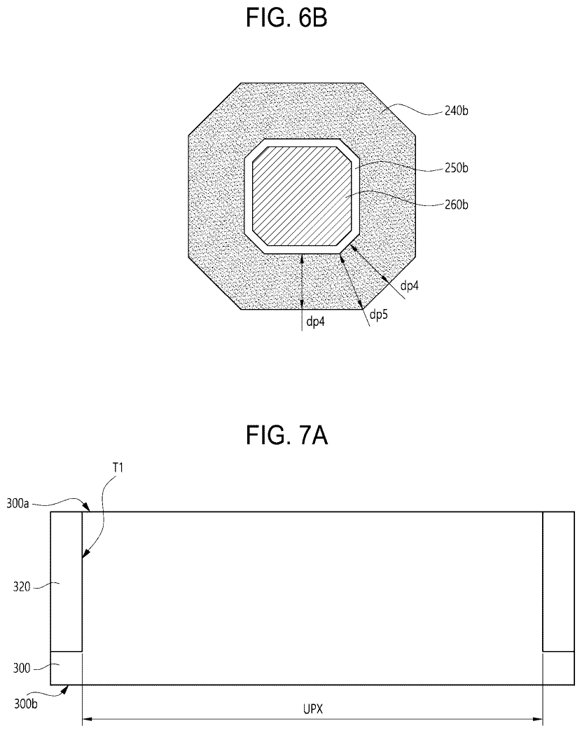

FIGS. 6A and 6B show plan views illustrating a photoelectric conversion element, a transfer gate, and a gate insulation layer based on some implementations of the disclosed technology. While the examples show different planar shapes of the photoelectric conversion element, a transfer gate, and a gate insulation layer, the differences will be described in the below. The description as discussed in relation to FIGS. 3-5 can be applied to the examples of FIGS. 6A and 6B as long as such description does not conflict with the description provided in the below.

Referring to the example as shown in FIG. 6A, the transfer gate 260a, the gate insulation layer 250a, and the photoelectric conversion element 240a have circular planar shapes. The photoelectric conversion element 240a is disposed to surround the transfer gate 260a while the gate insulation layer 250a is disposed between the transfer gate 260a and the photoelectric conversion element 240a. The photoelectric conversion element 240a has a same width dp3 along the boundary of the photoelectric conversion element 240a.

Referring to the example as shown in FIG. 6B, the transfer gate 260b, the gate insulation layer 250b, and the photoelectric conversion element 240b have octagonal planar shapes. The photoelectric conversion element 240b is disposed to surround the transfer gate 260b while the gate insulation layer 250b is disposed between the transfer gate 260a and the photoelectric conversion element 240a. With the octagonal planar shapes, the widths of the photoelectric conversion element 240b can be different along a boundary of the transfer gate 260b. The width dp4 of the photoelectric conversion element 240b may be same along the edges of the photoelectric conversion element 240b. The width dp5 of the photoelectric conversion element 240b, which is between the corner (or vertex) of the photoelectric conversion element 240 and the corner (or vertex) of the transfer gate 260b may be larger than the width dp4.

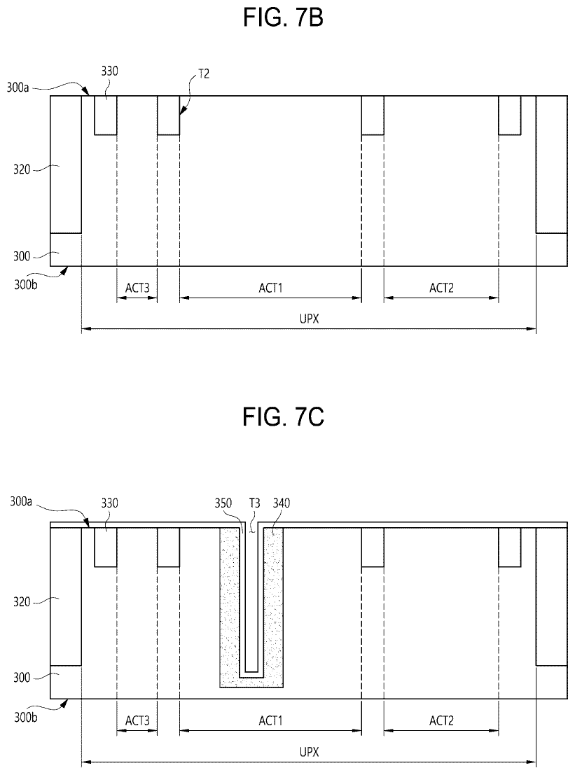

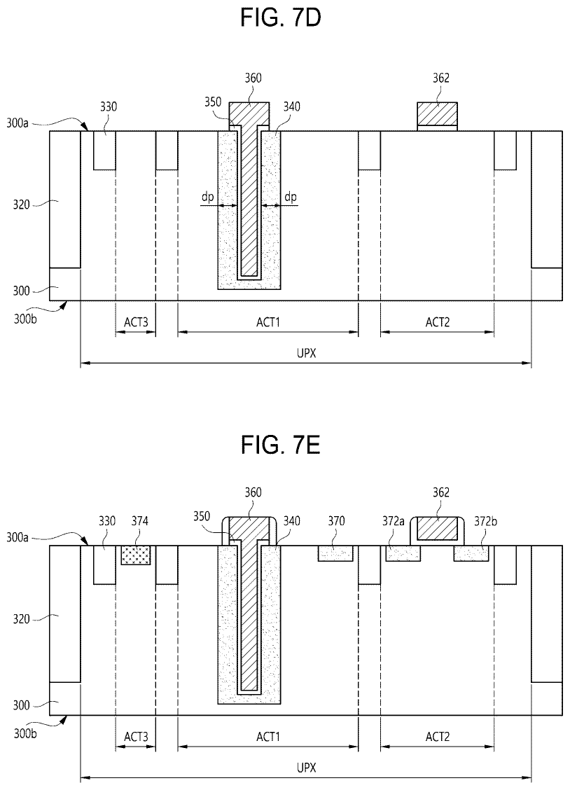

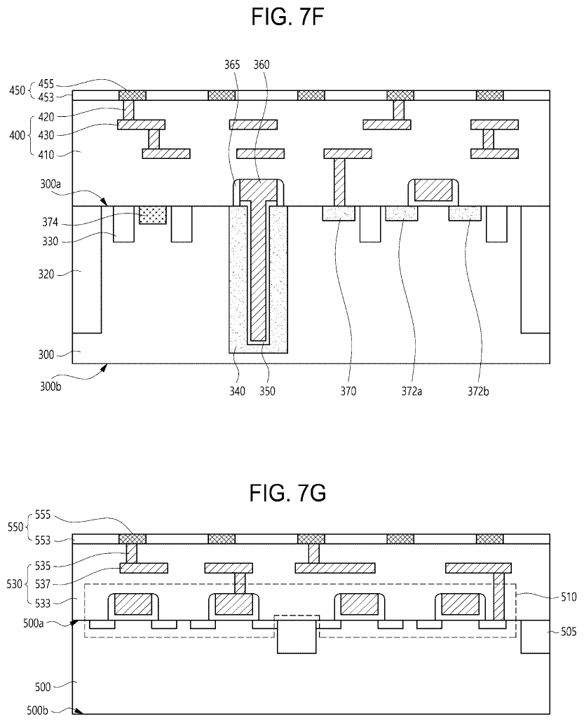

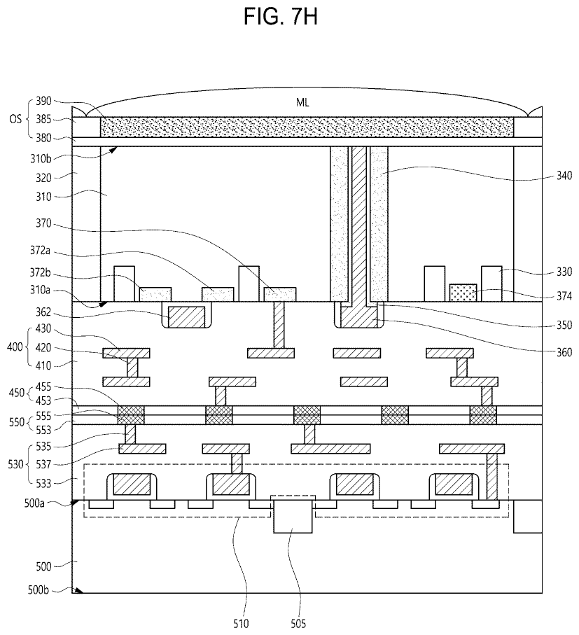

Hereinafter, with reference to FIGS. 7A to 7H, a method of manufacturing an image sensing device in accordance with example embodiments will be described.

Referring to FIG. 7A, a first substrate 300 may be prepared. The first substrate 300 may include a first surface 300a and a second surface 300b. The first surface 300a may be a front surface, and the second surface 300b may be a back surface. The first substrate 300 may include a first conductive type, such as a bulk silicon substrate including p-type impurities, an epitaxial layer including p-type impurities, or a semiconductor substrate including p-type wells.

A first trench T1 may be formed in a predetermined region of the first substrate 300. For example, after forming a mask pattern (not shown) on the first surface 300a of the first substrate 300, an exposed portion of the first substrate 300 may be etched to a set depth to form the first trench T1. A lower surface of the first trench T1 may be spaced by a predetermined distance from the second surface 300b of the first substrate 300. Subsequently, the mask pattern may be removed. At least one material layer may be formed in the first trench T1 to form a pixel isolation layer 220. The material of the pixel isolation layer 220 may include at least one of an insulation layer, a semiconductor layer including conductive dopants or a conductive layer.

Referring to FIG. 7B, a second trench T2 having a shallower depth than the first trench T1 may be formed in the first substrate 300 corresponding to the unit pixels UPX. At least one insulation layer may be formed in the second trench T2 to form a device isolation layer 330. By forming the device isolation layer 330, first to third active regions ACT1-ACT3 may be defined in the unit pixel UPX.

Referring to FIG. 7C, a selected region of the first active area ACT1 may be etched to form a third trench T3. The third trench T3 may have a depth equal to or less than the depth of the first trench T1.

A second conductive type impurity may be implanted into the first active region ACT1 corresponding to a sidewall and a bottom surface of the third trench T3 to form the photoelectric conversion element 340. For example, the second conductive impurity may include an n-type impurity opposite to the first conductive impurity. The conductive impurities to form the photoelectric conversion element 340 may be implanted via, for example, a vertical ion implantation process and an oblique ion implantation process. Accordingly, the photoelectric conversion element 340 may be formed to have a same bonding depth to an inner wall of the third trench T3. In example embodiments, when forming the photoelectric conversion element 340, a mask pattern (not shown) may be formed such that a periphery of the third trench T3 may be exposed. The mask pattern may be removed after the photoelectric conversion element 340 may be formed.

Next, a gate insulation layer 350 may be formed along the first surface 300a of the first substrate 300 and the surface of the photoelectric conversion element 340. The gate insulation layer 350 may include at least one of, for example, a silicon oxide layer, a silicon nitride layer, or a metal oxide layer. A cleaning process may be further performed between the step of removing the mask pattern configured to expose the third trench T3 and the step of forming the gate insulating layer 350.

Referring to FIG. 7D, a conductive layer is formed on the gate insulation layer 350. The conductive layer may be formed to a thickness such that the third trench T3 may be buried. In some cases, the conductive layer may be planarized so that a predetermined thickness may remain on the first surface 300a of the first substrate 300. The planarized conductive layer may be patterned to be positioned on the first active region ACT1 and the second active region ACT2 to form a transfer gate 360 in the third trench T3, and a gate 362 of a pixel transistor positioned on the second active region ACT2, hereinafter referred to as a pixel gate. For example, an upper surface 360a of the transfer gate 360 and an upper surface 362a of the pixel gate 362 may be located in the same plane.

Referring to FIG. 7E, an insulating spacer SP may be formed on both walls of the transfer gate 360 and pixel gate 362. Second conductive impurities may be implanted into selected portions of the first and second active regions ACT1 and ACT2. In example embodiments, a mask pattern (not shown) may be formed such that selected portions of the first active region ACT1 and the second active region ACT2 may be exposed. A high concentration of the second conductive impurity may be implanted into the exposed first active region ACT1 and second active region ACT2 to form a floating diffusion region 370 around the transfer gate 360 of the first active region ACT1 and to form a source 372a and a drain 372b of the pixel transistor in the second active region ACT2 on either surface of the pixel gate 362.

After removing the mask pattern for implanting the second conductive impurity, a mask pattern (not shown) may be formed such that a selected portion of the third active region ACT3 may be exposed

A high concentration of first conductive impurities may be implanted into the exposed third active region ACT3 to form a substrate contact region 374. Subsequently, a mask pattern (not shown) for forming the substrate contact region 374 may then be removed. Thereby, pixel devices including the transfer transistor, the floating diffusion region 370 and the pixel transistor may be formed on the first surface 300a of the first substrate 300 for each unit pixel UPX.

Referring to FIG. 7F, a first interconnection layer 400 may be further formed on the first surface 300a of the first substrate 300 on which the pixel elements may be formed. The first interconnection layer 400 may include a plurality of first conductive patterns, which may be indirectly connected to electrical components of the pixel elements (for example, floating diffusion or substrate contact regions), and the plurality of insulating interlayers configured to isolate the first conductive patterns, which may be provided with different signals. For example, the first conductive patterns may include a plurality of first vertical connections 420 and a plurality of first horizontal connections 430. The plurality of first vertical connections 420 and the plurality of first horizontal connections 430 may be stacked at least once alternately.

Further, a first bonding layer 450 may be formed on the first interconnection layer 400. The first bonding layer 450 may be formed in a following manner. First, a first bonding insulation layer 453 may be formed on the first interconnection layer 400. The first bonding insulation layer 453 may include at least one of a silicon oxide layer and a silicon nitride layer. Selected regions of the first bonding insulation layer 453 may be etched to form first pad holes (not shown) in the first bonding insulation layer 453. For example, the first pad holes may expose the plurality of first vertical connections 420 disposed adjacent to the first bonding layer 450. Next, a metal layer may be formed in the first pad holes to form first bonding pads 455. Accordingly, the first bonding pads 455 may be connected with at least one of the conductive patterns in direct or indirect connection with the electrical components of the pixel elements. Further, the first bonding pads 455 may be electrically isolated by the first bonding insulation layer 453. It should be appreciated that the first interlayer insulation layer 410, the first vertical connection 420 and the first horizontal connection 430 of FIG. 6F may be shown schematically for illustrative purposes only, and may be varied in various forms.

Next, referring to FIG. 7G, a second substrate 500 may be prepared. The second substrate 500 may have a first surface 500a and a second surface 500b that are opposed to each other. A device isolation layer 505 and logic transistors 510 may be integrated on the first surface 500a of the second substrate 500. A second interconnection layer 530 may be formed on the logic transistors 510. The second interconnection layer 530 may include at least one second insulating interlayer 533 and a plurality of second conductive patterns. The plurality of second conductive patterns may include, for example, a plurality of second vertical connections 535 and a plurality of second horizontal connections 537. The plurality of second vertical connections 535 and the plurality of second horizontal connections 537 may be stacked at least once alternately. The logic transistors 510 may be suitably connected by the plurality of second conductive patterns to form the logic assembly LA of FIG. 1. A second bonding layer 550 may be formed on the second interconnection layer 530. The second bonding layer 550 may include a second bonding insulation layer 553 and a plurality of second bonding pads 555. The plurality of second bonding pads 555 may be electrically connected to a plurality of second conductive patterns, such as a plurality of second vertical connections 535 disposed adjacent to the second bonding layer 550. Accordingly, the second bonding pads 555 are electrically connected with the logic circuit. The plurality of transistors may be electrically connected by the plurality of second conductive patterns to form the logic circuit. The plurality of second insulating interlayer 533 may electrically isolate the plurality of second conductive patterns.

A second bonding layer 550 may be formed on the second interconnection layer 530. For example, a second bonding insulation layer 553 may be formed on the second interconnection layer 530. A selected portion of the second bonding insulation layer 553 may be etched to form a plurality of second pad holes (not shown) such that a plurality of third conductive patterns 533 of the second interconnection layer 530 may be exposed. A metal layer may then be formed in the second pad holes to form a plurality of second bonding pads 555.

Next, referring to FIGS. 7G and 7H, the first substrate 300 may be stacked on the second substrate 500. At this time, the first substrate 300 may be placed on the second substrate with the first substrate 300 flipped so that the first bonding layer 450 of the first substrate 300 may face the second bonding layer 550 of the second substrate 500. Accordingly, the second surface 300b of the first substrate 300 may face outwardly.

Thereafter, the first substrate 300 and the second substrate 500 may be bonded, e.g., hybrid-bonded, to stack the first bonding layer 450 and the second bonding layer 550. For example, the first bonding insulation layer 453 and the second bonding insulation layer 553 may be physically bonded to each other. Thereafter, an annealing process may be performed to thermally bond the first bonding pad 455 and the second bonding pad 555. Accordingly, the pixel elements of the first substrate 300 and the logic transistors 510 of the second substrate 500 may be electrically connected with each other by the bonding process, e.g., the hybrid bonding process.

Next, the second surface 300b of the first substrate 300 may be grinded to expose the pixel isolation layer 320, thereby forming a pixel array substrate 310. The pixel array substrate 310 may have a relatively thinner thickness than the first substrate 300 by the grinding process. Further, even if the pixel isolation layer 320 may be formed by the front deep trench isolation (FDTI) method, the pixel isolation layer 320 may have a shape configured to penetrate the pixel array substrate 310 due to the grinding process. Thus, electrical and optical separation between neighboring unit pixels UPX may be achieved.

Furthermore, the transfer gate 360 and photoelectric conversion element 340 may have substantially the same depth as the depth of the pixel array substrate 310. Accordingly, the photoelectric conversion element 340 may have sufficient area for generating photoelectric charges and, more importantly, may be kept at a uniform distance from the transfer gate 360. Therefore, the photoelectric charges generated in the entire area of the photoelectric conversion element 340 may be easily transferred to the floating diffusion region 370 based on the control of the transfer gate 360.

The surface of the pixel array substrate 310 (hereinafter referred to as the second surface of the pixel array substrate 310: 310b) may further form a light incidence element. For reference, the first surface 310a of the pixel array substrate 310 may be the same as the first surface 300a of the first substrate 300.

The light incidence element may include, for example, an anti-reflective layer 380, a grid pattern 385, a color filter 390 and a micro lens ML.

First, the anti-reflective layer 380 may be formed on the second surface 310b of the pixel array substrate 310. For example, the anti-reflective layer 380 may include at least one of, but not limited to, silicon oxide, silicon nitride, silicon oxynitride, aluminum oxide, hafnium oxide, or combinations thereof.

The grid pattern 385 may be formed on the anti-reflective layer 380, which corresponds to the pixel isolation layer 320. By the grid pattern 385, a region to be formed by the color filter 390 may be scheduled. The grid pattern 385 may be formed of air, or of a stacked structure of air and conductive layers. The grid pattern 385 may prevent color mixing between adjacent different color filters 390.

The color filter 390 may be formed in a region surrounded by the grid pattern 385. For example, the color filter 390 may filter different colors of light based on a unit pixel UPX. Further, the color filter 390 may be formed in each color filter region, e.g., unit pixel UPX, using different color filter arrangements.

The micro lens ML may be formed at a position that overlaps the color filter 390 and photoelectric conversion element 340. The micro lens ML may focus an incident light onto the photoelectric conversion element 340. The micro lens ML of example embodiments may be illustrated in a hemispherical shape, but is not limited thereto, and any structure capable of focusing light onto the cylindrical photoelectric conversion element 340 is of course included herein.

As described in more detail above, according to example embodiments, the transfer gate of the unit pixel may be configured to penetrate the interior of the pixel array substrate. The photoelectric conversion element may be formed to surround the sidewall of the transfer gate, and to have the vertical extension length equal to or less than a vertical extension length of the transfer gate in the pixel array substrate. Accordingly, the entire area of the photoelectric conversion element may be controlled at the constant distance from the transfer gate, thereby improving the charge transfer characteristics to the floating diffusion area. By the improvement of the charge transfer characteristics, the Gm characteristic, the conversion gain may be secured, and the noise may also be improved, which ultimately improves the image quality of the image sensing device.

While the present invention has been described in detail with reference to preferred embodiments, the invention is not limited to the above embodiments, but is capable of many modifications by those having ordinary skill in the art within the scope of the technical ideas of the invention.

What is claimed is:

1. An image sensing device comprising:
a substrate having a first surface and a second surface opposite to the first surface;
a plurality of unit pixels supported by the substrate, each unit pixel configured to include a photoelectric conversion element that converts incident light into photocharge; and
a transfer gate provided in each of the plurality of unit pixels to transfer the photocharge out of the photoelectric conversion element, the transfer gate extending vertically along a vertical direction from the first surface to the second surface of the substrate with a first length,
wherein, in each unit pixel, the photoelectric conversion element is configured to extend along the vertical direction with a second length that is equal to or less than the first length of the transfer gate.

2. The image sensing device of claim 1, wherein the photoelectric conversion element has an outer wall that is distanced from a sidewall of the transfer gate by a same distance along a boundary of the transfer gate.

3. The image sensing device of claim 1, further comprising a gate insulation layer interposed between a sidewall of the transfer gate and an inner sidewall of the photoelectric conversion element.

4. The image sensing device of claim 1, wherein an extension length of the transfer gate in the substrate corresponds to a length from the first surface to the second surface of the substrate.

5. The image sensing device of claim 1, further comprising a floating diffusion region formed on the first surface of the substrate.

6. The image sensing device of claim 5, further comprising at least one pixel transistor formed on the first surface of the plurality of unit pixels to generate a pixel signal based on an amount of charge charged stored in the floating diffusion region.

7. The image sensing device of claim 1, further comprising a pixel isolation layer formed in the substrate to define areas for the plurality of unit pixels.

8. The image sensing device of claim 7, wherein a depth of the pixel isolation layer is equal to the second length of the photoelectric conversion element.

9. An image sensing device comprising:
a first substrate having a front surface and a back surface, the first substrate including pixel elements and a first bonding layer electrically connected to the pixel elements, the pixel elements and the first bonding layer being disposed on the front surface, and the first substrate further including a light incidence element disposed on the back surface; and
a second substrate bonded to the first bonding layer and including a logic circuit on the front surface of the first substrate and a second bonding layer electrically connected to the logic circuit,
wherein each pixel element comprises:
a transfer gate extends along a vertical direction with a first extension length in the first substrate;
a photoelectric conversion element formed in the first substrate and surrounding a sidewall of the transfer gate, the photoelectric conversion element extending along the vertical direction with a second extension length that is equal to or less than the first extension length; and
a floating diffusion region positioned on the front surface of the first substrate on one side of the photoelectric conversion element and configured to selectively receive charges generated by the photoelectric conversion element based on an operation of the transfer gate.

10. The image sensing device of claim 9, wherein the photoelectric conversion element has an outer wall that is distanced by a distance from the sidewall of the transfer gate along a boundary of the transfer gate.

11. The image sensing device of claim 9, further comprising a gate insulation layer interposed between the transfer gate and the photoelectric conversion element.

12. The image sensing device of claim 9, wherein the pixel elements further comprise at least one pixel transistor disposed on the front surface of the first substrate to be adjacent to the floating diffusion region, the at least one pixel transistor configured to selectively generate a pixel signal based on an amount of charges provided to the floating diffusion region.

13. The image sensing device of claim 9, further comprising:
a first interconnection layer electrically connected between the pixel elements and the first bonding layer; and
a second interconnection layer electrically connected between the logic circuit and the second bonding layer.

14. The image sensing device of claim 9, further comprising a pixel isolation layer formed in the first substrate to define a plurality of unit pixels.

15. The image sensing device of claim 14, wherein an extension length of the pixel isolation layer is equal to the first extension length or the second extension length.

16. The image sensing device of claim 14, wherein the light incidence element comprises:
an anti-reflective layer disposed on the back surface of the first substrate;
grid patterns disposed on a surface of the anti-reflective layer and located at a location corresponding to the pixel isolation layer;
a color filter disposed between the grid patterns; and
a micro lens disposed on the color filter and configured to focus an incident light onto the photoelectric conversion element.

17. A method of manufacturing an image sensing device, the method comprising:
etching a front surface of a first substrate having unit pixels by a set depth to form a trench;
implanting conductive impurities into the trench to form a photoelectric conversion element;
forming a gate insulation layer on the front surface of the first substrate with the trench;
forming a conductive layer on the gate insulation layer to fill the trench;
patterning the conductive layer to form a transfer gate;
implanting impurities onto a region disposed on the front surface of the first substrate and at one side of the transfer gate to form a floating diffusion region; and
grinding a back surface of the first substrate to expose the transfer gate.

18. The method of claim 17, further comprising, between the forming of the floating diffusion region and the grinding of the first substrate:
forming, on the front surface of the first substrate, a first bonding layer including first bonding pads electrically connected to the transfer gate and the floating diffusion region, ;
forming at least one logic transistor on the front surface of a second substrate to form a logic circuit;
forming, on the logic circuit, a second bonding layer including a second bonding pad electrically coupled to the logic circuit, ; and
bonding the first bonding layer to the second bonding layer to stack the first substrate and the second substrate.
